(19) United States
(12) Patent Application Publication
(10) Pub. No.: US 2016/0234940 A1
(43) Pub. Date: Aug. 11, 2016

(54) Long lasting protection of flexible printed circuit board strips

(71) Applicant: Dmitry Konstantinovich Shaytan, Moscow (RU)

(72) Inventor: Dmitry Konstantinovich Shaytan, Moscow (RU)

(21) Appl. No.: 14/619,190

(22) Filed: Feb. 11, 2015

(51) Int. Cl. H05K 1/18

(52) U.S. Cl. CPC H05K 1/181; H05K 2201/05

(57) ABSTRACT

This invention relates to means for protecting flexible printed circuit board strip (FPCBS) from mechanical and long lasting chemical effects caused by water and other chemical elements in it. Particularly, this invention relates to cases when FPCBSs are bending in different directions from external forces and/or have continuous immersion into water or into other hazardous environments for electronics. For example cases can be but not limited:
to continuous lighting and signaling systems based on FPCBS in swimming pools, for example, at a bottom of a swimming pool to visualize or track training for swimmers, or to visualize water polo playing field areas;
to set continuous lighting and signaling systems for other purposes in wet environments, for example, on or under water surfaces, on natural and artificial objects with immersion in water;
to set continuous lighting and signaling systems on surfaces without rigid mounting of the systems.

The embodiment comprises form a flexible printed circuit board strip placed inside a flexible hollow tube. The said flexible hollow tube has dimensions allowing said flexible printed circuit board strip to turn around it longitudinal axis. The said flexible hollow tube has air or any other gas pressure inside it. At least one end of said flexible hollow tube has means for connection of pressure source of air or other gas. At least one end of said flexible hollow tube has means for sealed connection of electrical wires going from said flexible printed circuit board strip to power supply and or control device.

### CROSS-REFERENCE TO RELATED APPLICATIONS

U.S. 61/941,591 date 19 Feb. 2014, RU2014104740 date 12 Feb. 2014.

### FEDERALLY SPONSORED RESEARCH

None

The following is tabulation of some prior art that presently appears relevant:

### U.S. Patents

| Patent Number | Kind Code | Patentee |
|---|---|---|
| 6,054,509 | A | Hitoshi Arai |
| 8,388,182 | B2 | Chia-Hao Chang |
| 8,641,229 | B2 | Qing Charles Li |
| 8,262,250 | B2 | Qing Charles Li |
| 6,074,074 | A | Armin Marcus |
| 6,076,936 | A | Ben George |
| 4,107,767 | A | Jacques Anquetin |
| 4,607,317 | A | Ta-Yen Lin |
| 5,934,792 | A | Richard J. Camarota |
| 6,592,238 | B2 | Mark Joseph Cleaver |
| 6,761,472 | B1 | Mark Joseph Cleaver |
| 7,210,818 | B2 | John F. Luk |

### U.S. Patent Application Publications

| Publication Number | Kind Code | Patentee |
|---|---|---|
| 20140085896 | A1 | Qing (Charles) Li |
| 20050092517 | A1 | Ben Fan |
| 20130170191 | A1 | Patrick Marc Perquy |
| 20050231947 | A1 | Thomas Sloan |

### Foreign Patent Documents

| Foreign Doc. Nr. | Cntry Code | Kind Code | Patentee |
|---|---|---|---|
| 102012214492 | DE | A1 | Thomas Donauer |
| 102012214488 | DE | A1 | Martin Reiss |
| 102007043716 | DE | A1 | Michael Dr. Loddoch |
| 202012011553 | DE | U1 | Benjamin Berndt |
| 102005041333 | DE | A1 | Michael Schillinger |
| 2685157 | EP | A3 | Ferdinand Pfleghart |

### FIELD OF THE INVENTION

This invention relates to means for protecting flexible printed circuit board strip (FPCBS) from mechanical and long lasting chemical effects caused by water and other chemical elements in it. Particularly, this invention relates to cases when FPCBSs are bending in different directions from external forces and/or have continuous immersion into water or into other hazardous environments for electronics. For example cases can be but not limited:
to continuous lighting and signaling systems based on FPCB strips in swimming pools, for example, at a bottom of a swimming pool to visualize or track training for swimmers, or to visualize water polo playing field areas;
to set continuous lighting and signaling systems for other purposes in wet environments, for example, on or under water surfaces, on natural and artificial objects with immersion in water;
to set continuous lighting and signaling systems on surfaces without rigid mounting of the systems.

### BACKGROUND OF THE INVENTION

### How Idea of the Invention Came to My Mind

During the whole 2013 year I tried to find solution to protect a flexible printed circuit board strip (FPCBS) of about 25 and 50 meters long at a swimming pool bottom. FPCBSs were fully and constantly submersible for more than six month at various 25 and 50 meters swimming pools.

At a functioning swimming pool there was hard to fix FPCBS rigidly due to complexity of underwater operations or of risk to breach impermeability of the swimming pool basin (shell).

FPCBSs were part of a system used by coachers to program training for swimmers at a computer. FPCBS's function was to visualize the training schedule at the bottom. FPCBSs had circuits, microelectronic components, and light emitted diodes (LEDs) that required mechanical and chemical protection.

Prior art solutions of the protection failed to provide FPCBSs stable functioning in a long time frame. My target was a stable functioning for FPCBSs from one to two years.

In my tests FPCBSs with electronic components protected by prior art means and methods failed to function in a time frame of approximately from one to 3 months of constant immersion into swimming pool water. The most long lasting time of functioning of electronic circuits in three month time frame was related to the manufacturing quality of applied prior art means and methods but it was not related to said means' and methods' principals. In other words they were not adequate for the FPCBSs functioning in harsh conditions of substantial concentration of molecules destructive for electronic circuits and/or in harsh conditions of FPCBS displacements, bending from external forces. The displacements, or bending, were caused by non-rigid fixing, swimmers, children, currents, waves, and cleaning equipment. The FPCBS protection was also tested on water surfaces with waves and currents.

### DESCRIPTION OF THE PRIOR ART

Conventional means and methods of protecting flexible printed circuit board strips (FPCBS) are very common in protecting FPCBSs with light emitting diodes circuits (FPCBSLED). The said common means and methods are based on two types of protection of FPCBSLEDs that are usually combined to provide mechanical and chemical protection.

The first type of protection is the FPCBSLED encapsulation by elastic polymers, like epoxy resins, polyurethanes, polyvinyl chlorides, silicones, and similar. Encapsulation is done though adhesive technology (like, dipping glue type, or extruding) of said polymers at the FPCBSLED and electronic circuits in it. The said protection usually enhanced through insertion of the FPCBS into a soft squeezable container, like U-tube. The said container is made from the said polymers and has width, height, and length dimensions approximately equal to the FPCBS's ones, and thickness of approximately 1.00 mm (please, see reference examples of marketing products http://www.denoled.com/products/led-strip-light/Waterprool-SMD-5050-Flexible-LED-Strips-With-Silicone-Tube-and-Silicone-Glue.html, or there http://www.heroicrobotics.com/products/strip). Similar encapsulations can be found in patents and applications: U.S. Pat. No. 6,054,509, U.S. Pat. No. 8,388,182B2, US200510092517A1, DE102012214492A1, DE102012214488A1, DE102007043716A1, U.S. Pat. No. 8,641,229B2, U.S. Pat. No. 8,262,250B2, and US2014/0085896.

The second type of said protection is the FPCBS housing into profiles (reference examples are here http://www.ledlightsworld.com/led-strips-led-aluminium-housing-c-1_103.html, or here https://www.led-lighthouse.co.uk/led-strip-lights/led-strip-aluminium-profile, or here http://www.ledson.eu/led-profiles#/led-profiles/) that are made from metals, or hard polymers, or plastics. The said housing profiles are used for FPCBSLEDs mounting on a hard surface and for their protection from hard mechanical impacts that can stress the FPCB strip. The similar protection method can be found in patents and applications: U.S. Pat. No. 6,074,074, DE202012011553U1, U.S. Pat. No. 6,076,936, and US2013/0170191A1.

Chemical and mechanical protection can be achieved by combining the above two types of protection in certain environments. However, to enhance said protection there is required increase of mass (volume) of said elastic polymers surrounding the FPCBS, as if increase of solidity of said housing profiles.

Elastic polymers have some permeation for water molecules and other elements in it. (for example, silicon permeability coefficient can be found there: http://en.wikipedia.org/wiki/Permeation, http://www.silicone-polymers.co.uk/pdf2011/Moisture%20Permeability%20of%20Silicone%20Systems%20-%20Case%20Study%202.pdf). Permeation happens by diffusion or micro-cracks and other breaches. Degradation of mechanical characteristics of said polymers causes micro-cracks and it is more substantial in salted and swimming pool chemical waters than in pure water.

Said increase of mass (volume) of said elastic polymers surrounding the FPCBS doesn't reasonable from the following points of view: economical, mechanical properties, and present design of mass production manufacturing equipment for FPCBS encapsulation.

The said housing profiles are not efficient for protecting FPCBSs in cases of mounting on surfaces without rigid mounting; let's say without said profiles immobilization. The mechanical forces start to bend said profiles, the longer profile the larger bending. Here are examples of cases, but not limited to the following examples, where rigid mounting of profiles is inconvenient or not reasonable from economical and engineering point of view: bottom of a swimming pool full of water, unstable surfaces like water, sand, clay, and similar.

Housing profiles for FPCBSLEDs have internal width and height dimensions approximately equal to FPCBSLED's dimensions that cause said housing profiles to stress the FPCBS inside them during profiles bending. For example, in case of a long FPCBS of approximately 25 or 50 meters in a 25 or 50 meters swimming pool said housing profiles will have fluctuations of several meters and more.

Increase of said housing profiles stiffness (inflexibility) is not reasonable from practical point of view while their mounting on said surfaces is not simple, or require qualified underwater operations, and in case of swimming pool there is a risk to breach impermeability of the swimming pool basin (shell).

Stiffness (inflexibility) of said housing profiles is important for the following reason. FPCBS is flexible in one plane and rigid in the other. FPCBS is flexible only when mechanical force vector is approximately perpendicular to the FPCBS's plane of its width. FPCBS is rigid (non-flexible) in a case when mechanical force vector is parallel to the FPCBS's plane of its width; let's call it a side force. FPCBS has a mechanical stress when the FPCBS is in said housing profile that bends from a side force. The profile or system of those profiles is flexible but FPCBS is rigid in this plane.

The said mechanical stress becomes also possible in case of larger volumes of said polymers being used for encapsulation. When polymers mechanical characteristics of stiffness start to dominate over the FPCBS ones than encapsulated FPCBS has no room to avoid stress caused by said side forces over the polymer-FPCBS system.

The other type of prior art is related to so called flexible lighting systems. Let's call it the third type of protection. These systems comprise from light sources connected by wires, encapsulation and/or casing of them in flexible polymers. However, said systems use wires, not FPCBS, to connect electric components. Hence, there is no problem with said side forces that stress FPCBS. Examples of the flexible lighting systems can be found in patents and applications: U.S. Pat. No. 4,107,767, U.S. Pat. No. 4,607,317, U.S. Pat. No. 5,934,792, U.S. Pat. No. 6,592,238B2, U.S. Pat. No. 6,761,472B1, US2005/0231947A1.

Also there are solutions with the use of protective casing related to continuous lighting systems (CLS). Let's call it the fourth type of protection. In this protection casing continuousness is done by using modules. In the patent EP1498656 “Lighting device, in particular tunnel lighting” the elimination device comprises of a circuit boards, protective casing, and longitudinal joints having additional connection elements by screws. Elimination devises are fixed to provide stable (rigid) fixing, for example, in a wall in a tunnel. In this invention there is no mention about what type of printing circuit boards are used flexible or rigid. The above invention, EP1498656, has the following disadvantages for cases when systems are bending from external forces and/or have constant immersion into water or other hazardous environment for electronics: the modular casing approach to create the continuous lighting system (CLS), the requirements to fix modules, and to insulate or waterproof each module and connections among modules (FIGS. 2A-B, 4, 5, 7).

The next patent for modular CLS is U.S. Pat. No. 8,641,229B2 (with previous related ones U.S. Pat. No. 8,262,250B2, US2014/0085896A). They have separate modular casing approaches for flexible printed circuit board strips (FPCBS) and for rigid printed circuit board strips (RPCBS). A FPCBS protection is shown in the U.S. Pat. No. 86,412,229 at FIGS. 1A-B, 2A-B, 3A-B, 4A-B, 6A-E. The protection is similar to the said first type of protection, encapsulation of modules by elastic polymers, a colloid coating. For a RPCBS protection there is a protective casing in addition to the colloid coating. The RPCBS protection is shown in the U.S. Pat. No. 86,412,229 at FIGS. 7A-E, 8A-D, 13A-E, 14; in the U.S. Pat. No. 8,262,250 at FIGS. 12A-B, 14; in the application US2014/0085896 at FIGS. 7A-C, 8A-E, 9A-E, 10A-E. The above inventions (U.S. Pat. No. 8,641,229B2, U.S. Pat. No. 8,262,250B2, US2014/0085896A) have the following disadvantages for cases when the systems are bending from external forces and/or have constant immersion into water or other hazardous environment for electronics: the modular casing approach to create the continuous lighting system, the requirements to fix modules, and to insulate or waterproof each module and connections among modules. The similar to the above encapsulated solutions with the similar disadvantages are in patents EP2685157A2, DE102005041333, U.S. Pat. No. 7,210,818B2.

The fifth type of protection is wrapping of the FPCBS by thermoplastic film. For example, as it is in the U.S. Pat. No. 8,388,182B2 at FIGS. 1 and 2 item 50. This approach enhances chemical protection but doesn't solve said side forces problem that stress the FPCBS in the continuous systems without rigid mounting.

### Summary of the Prior Art Disadvantages

The prior art devices, means and methods have following problems in long lasting protection of the FPCBSs that operate in harsh conditions of substantial concentration of molecules destructive for electronic circuits and/or harsh conditions of the FPCBSs displacements or bending (for example, caused by waves, currents, people activities like playing or training, working equipment like a pool vacuum cleaner, and etc).

One problem is that encapsulating elastic polymers (for example, epoxy resins) are permeable for water and other molecules. For example, silicon permeability coefficient can be found there, http://en.wikipedia.org/wiki/Permeation, http://www.silicone-polymers.co.uk/pdf2011/Moisture%20Permeability%20of%20Silicone%20Systems%20-%20Case%20Study%202.pdf). Moreover said elastic polymers degradation causes microcracks that substantially increase molecules penetration and the FPCBS degradation. Increase of mass (volume) of said encapsulating surrounding the FPCBS doesn't reasonable from the following point of views: economical, mechanical properties, and present design of mass production manufacturing equipment for FPCBSs encapsulation.

The other problem is that in the continuous systems said housing profiles (from second type of protection) are not rigid enough to withstand displacements or bending from the external forces. Rigid mounting (holding) is not reasonable on the unstable surfaces or environments and in some objects, for example, in a swimming pool or pond bottoms. The said housing profiles bend that cause the stress of the FPCBS inside them that doesn't have flexibility in the side direction. The FPCBS is flexible only when mechanical force vector is approximately perpendicular to the FPCBS's plane of its width. FPCBS is rigid (non-flexible) in a case when mechanical force vector is parallel to the FPCBS's plane of its width. Also the said housing profiles do not protect FPCBS from said permeation.

The next problem is related to modular structure of the prior art of the continuous lighting systems. Modular structure is convenient for logistic operations, the system adjustment for onsite design, repairing by modules. However, there are the following disadvantages for cases when systems are bending in different directions from external forces and/or have constant immersion into water or other hazardous environment for electronics: the modular casing approach to create the continuous lighting system, the requirements to fix modules, and to insulate or waterproof each module and connections among modules.

### SUMMARY OF THE INVENTION

My objective was to create a utility model that would solve the said permeation and the said mechanical bending problems for long lasting protection of the FPCBSs inside the continuous systems that operate in said harsh conditions.

The invention has one or more aspects to extend (increase) a life time and time of non repairable operation of the FPCBSs in said harsh conditions.

One possible embodiment of the disclosed continuous system comprises:
a. a flexible printed circuit board strip placed inside a flexible hollow tube,
b. said flexible hollow tube has dimensions allowing said flexible printed circuit board strip to turn round along it longitudinal axis,
c. said flexible hollow tube has air or any other gas pressure inside it,
d. at least one end of said flexible hollow tube has means for connection to pressure source of air or other gas,
e. at least one end of said flexible hollow tube has means for sealed connection of electrical wires going from said flexible printed circuit board strip to power supply and or control device.

On the one hand, the said gas pressure reinforces the flexible hollow tube and keeps it from collapsing or crumpling or crushing down. This ensures that despite of the flexible hollow tube bending the FPCBS always has a room for turning round along it longitudinal axis. This turn allows the FBSBS to avoid stress from the side forces bending, in a direction where the FPCBS is rigid.

On the other hand, the said gas pressure stops permeation of hazardous molecules through microcracks, and other breaches.

The embodiment has one whole casting with gas pressure and FPCBSs inside. The flexible hollow tube casing can have inserted or incut means like nozzles, fittings, branch pipes, couplings, unions, ferrules, clutches, clamps, caps for purposes of connecting air pressure source, sealed connection of electrical wires, or elongation of the flexible hollow tube.

Inside the hollow tube ends of FPCBS can be connected (fixed) by springs or elastic materials to inserted or incut said means. In a case of the system constant movements (bending) in different directions these springs or elastic materials restrict the FPCBS to twist along longitudinal axis. At the same time these springs or elastic materials compensate differences in the elasticity of the FPCBS and the flexible hollow tube and protect the FPCBS from stress in longitudinal axis.

The said flexible hollow tube allows to produce the whole continuous system according to client required dimensions, for example, around 25 meters or 50 meters or 100 meters and more, and to roll it in a compact size for shipment. On the client's site the system just unrolled and connected to air pressure source, power supply, and digital control equipment. This feature solves the module system problems.

The flexible hollow tube casing can be made from reinforced or not reinforced polymer materials.

If the continuous system is fully submersible than the flexible hollow tube has a weight or weights attached along the flexible hollow tube to compensate or to get negative buoyancy.

Said weights, for example, can be attached by spinning around the flexible hollow tube.

The proposed embodiment doesn't require fixations (mounting) along the system. Just two ends can be fixed to keep the continuous system in place, bending is not a problem. The said encapsulation of the FPCBS into elastic polymers, for example, epoxy resins, can be in common volumes (masses) as for FPCBSLEDs protection standards of IP63, or IP 64, or IP65, or IP66, or IP67, or IP68. The FPCBSs interconnections and its connection to power or digital control wires don't require waterproof engineering requirements and standards. Long lasting reliable water proofing of these FPCBS connections for fully submersible systems is a chemical and mechanical engineering challenge. In the proposed embodiment this is not an issue. The cable for power and digital control that going out of the said hollow tube casing is sealed by common prior art means mostly for the purpose to keep air (gas) pressure inside the casing. The sealed connection can be placed not only in water or other hazardous environment but also out of it, in a safe place.

### BRIEF DESCRIPTION OF THE DRAWINGS

FIG. 1A-FIG. 1D is a sectional view of the FPCBS inside the hollow tube that show the FPCBS movements to avoid stress in case of lateral forces.

FIG. 1F-FIG. 1G is a top view of the hollow tube part where the FBCPS is inside to show bending form the lateral (side) forces.

FIG. 2A-FIG. 2C is a broken side view of different embodiments.

FIG. 2D is a perspective side view of one of the embodiments.

FIG. 3A-FIG. 3D is a sectional view of different embodiments.

FIG. 4A-FIG. 4B is a side view to show weights that keep the hollow tube casing with the FPCBSs under water.

### DETAILED DESCRIPTION OF THE INVENTION

The present invention will be now described more fully with the reference to accompanying drawings. The following detailed description is presented for the purpose of describing certain embodiments in detail and is, thus, not to be considered as limiting the invention to the embodiments described. Rather than the true scope of the invention is defined by the claims. Additionally, any features of any embodiment described herein are equally applicable to any other embodiments envisioned by one of ordinary skill in the art.

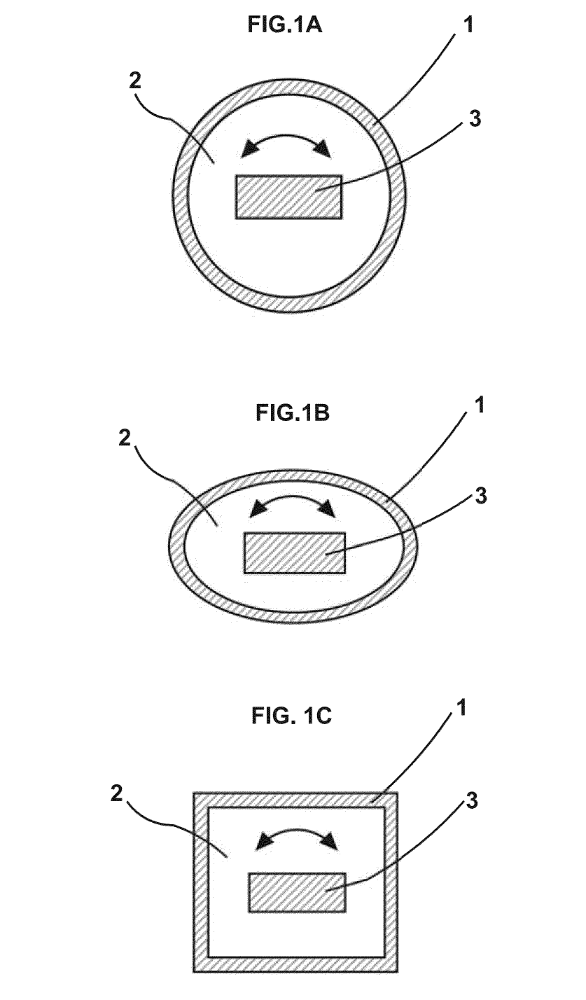

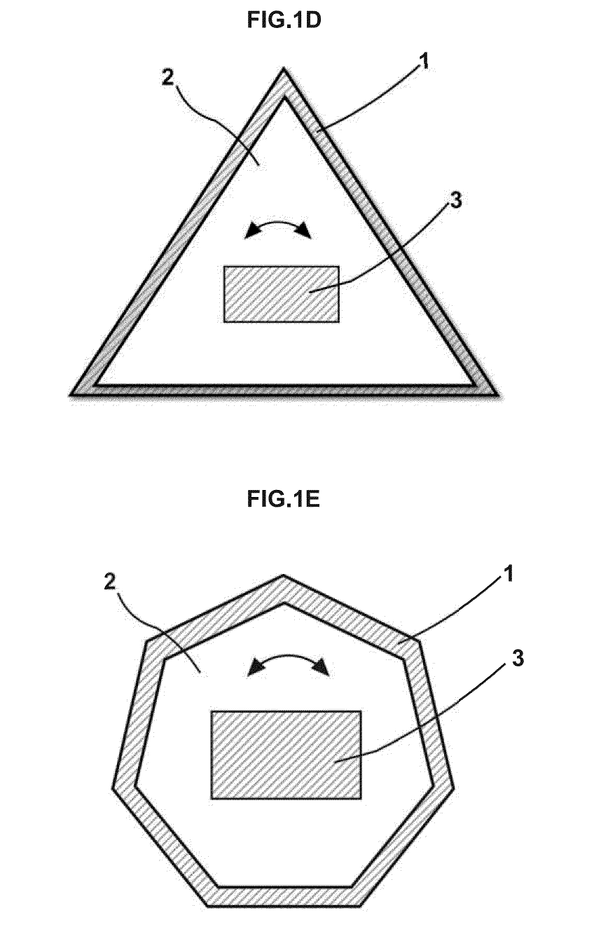

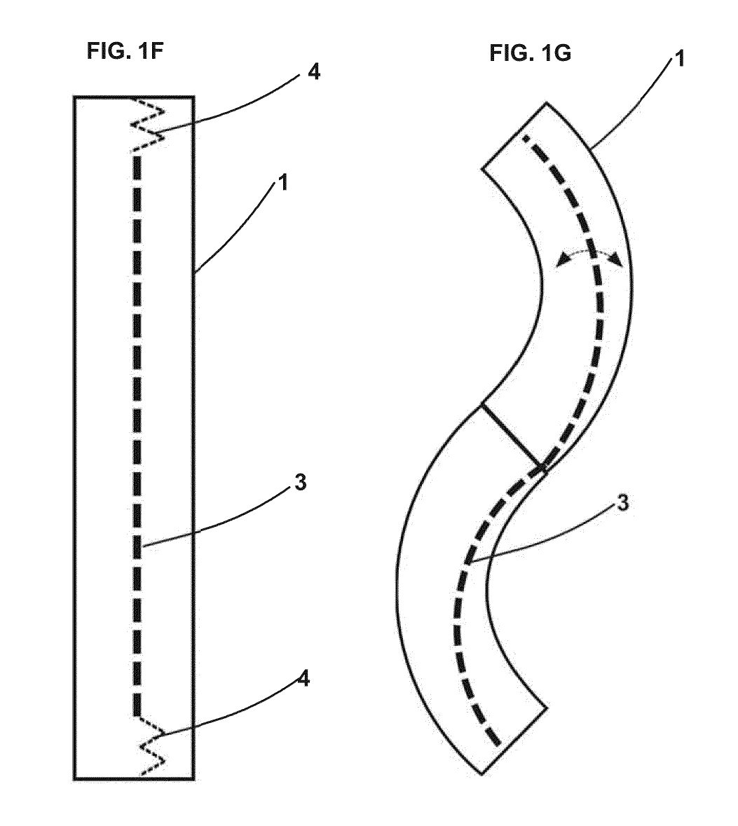

FIGS. 1A, 1B, 1C, 1D, and 1E sectional views show various shapes of the flexible hollow tube 1 under internal gas pressure 2 and the flexible printed circuit board strip (FPCBS) 3 inside. The curved line with both side arrowheads shows the turning motion of the FPCBS 3 when the flexible hollow tube 1 bends by forces horizontal to the drawing orientation on the page. FIG. 1G shows the flexible hollow tube 1 bending with the FPCBS inside.

The flexible hollow tube 1 is under internal air pressure 2 that create a safe space around the FPCBS 3 with dimensions allowing the FPCBS 3 to turn around it longitudinal axis. The FPCBS 3 comprises from one whole or from number of connected flexible printed circuit board strips. At effect of mechanical force applied to the flexible hollow tube 1 the FPCBS 3 turns so that a mechanical force vector is approximately perpendicular to the FPBCS's plane of the most flexibility. Due to said turn the FPCBS 3 avoid destructive tensions in planes where FPCB strip is worse flexible, for example, in lateral displacements. At FIGS. 1A, 1B, 1C, 1D, 1E, 1G the curved line with both side arrowheads shows this motion of the FPCBS 3. Types of shape of the flexible hollow tube 1 don't significantly affect the FPCBS 3 turning and the embodiment functioning. Examples of various shapes of the flexible hollow tube 1 are presented at FIGS. 1a, 1B, 1C, 1D, and 1E.

To avoid the FPCBS 3 twisting in extreme conditions, for example, on a wavy water surface where the flexible hollow tube 1 experience constant periodic deformations, means 4 are used to stabilize the FPCB strip 3. Means 4 are springs or elastic materials that compensate differences in elasticity between the FPCBS 3 and the flexible hollow tube 1, and restrict the FPCBS 3 to twist along longitudinal axis.

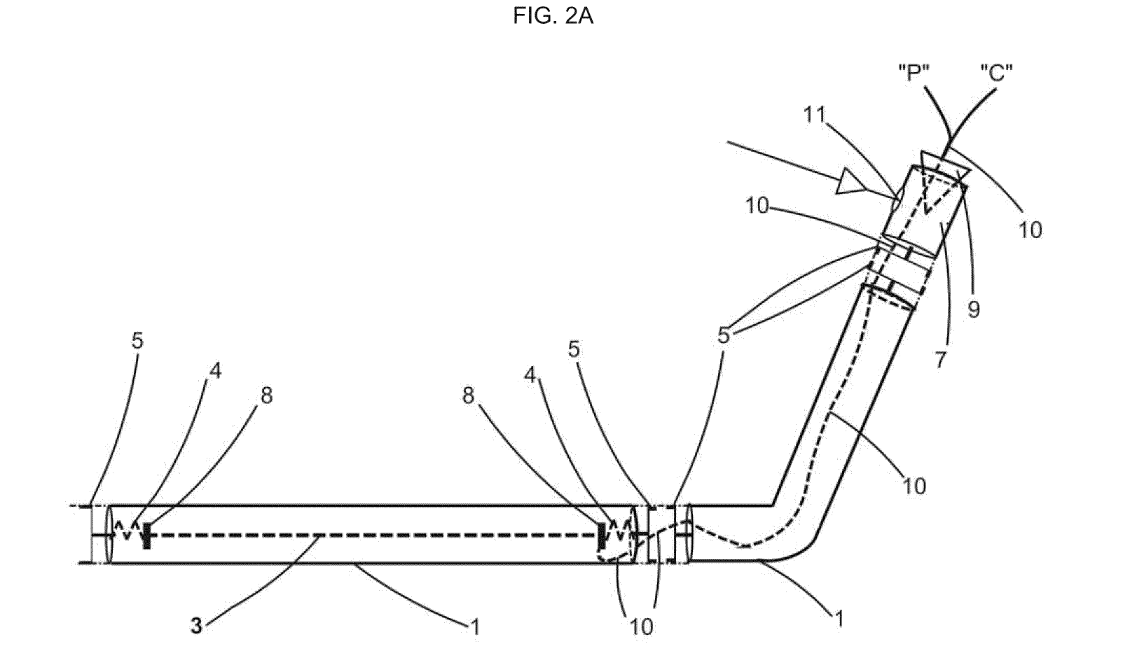

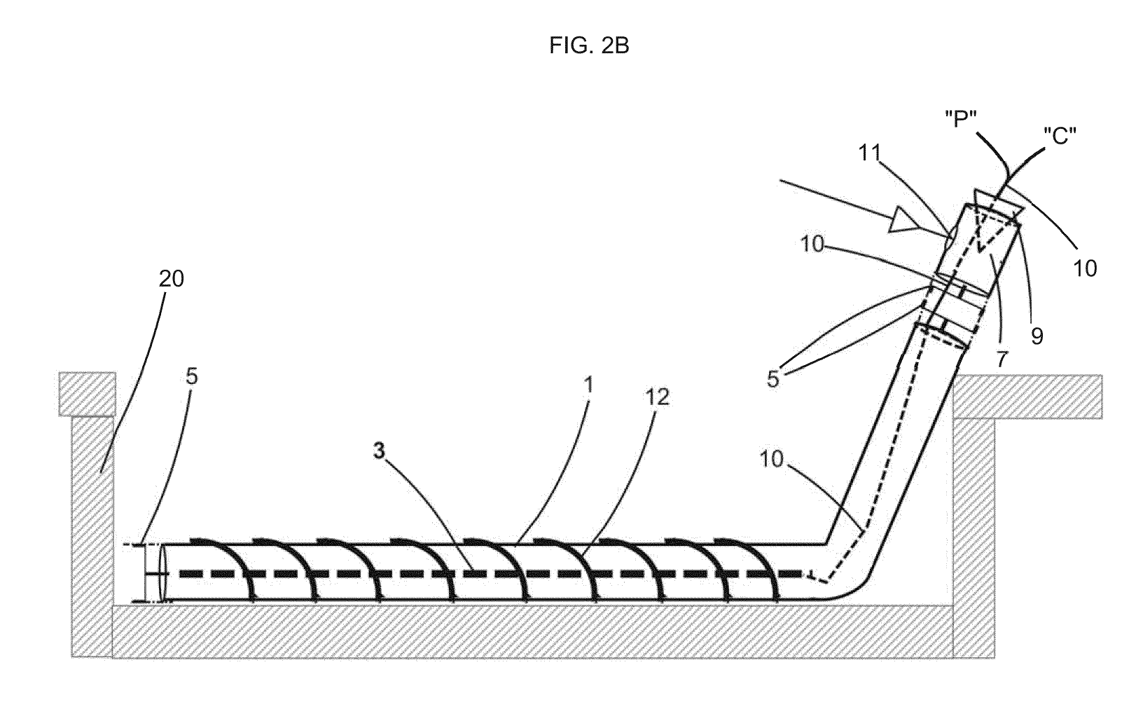

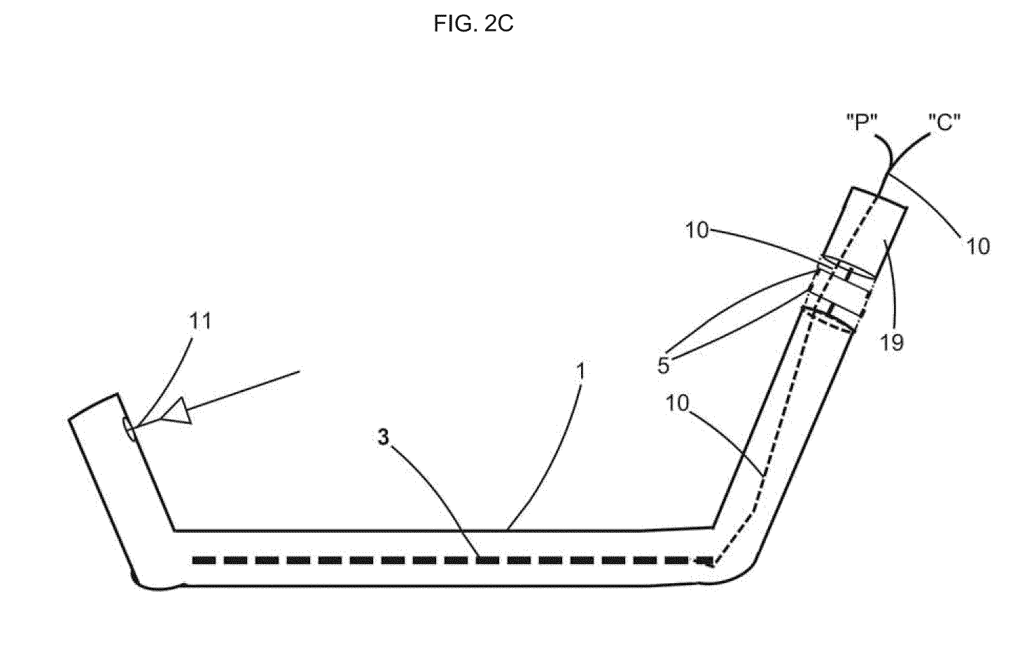

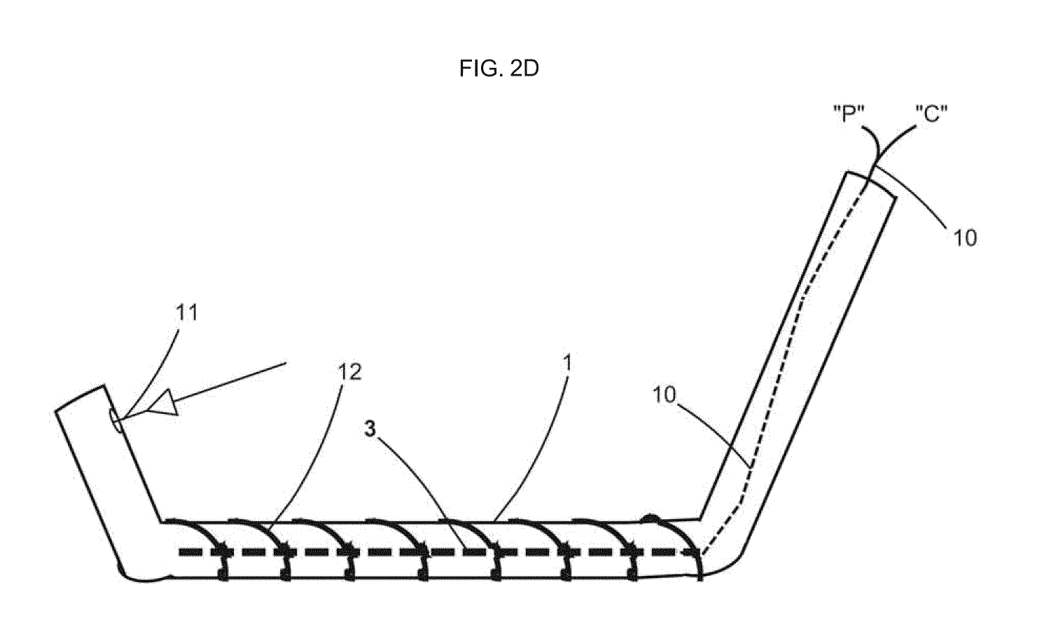

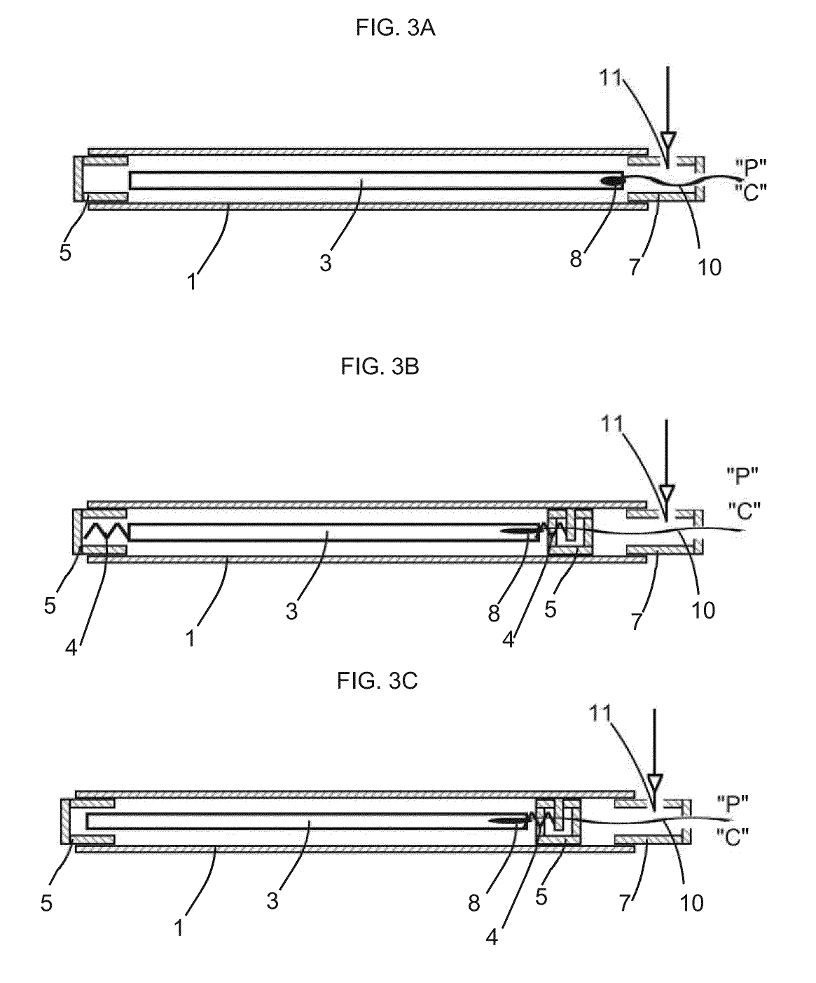

At FIGS. 2A, 3B, and 3C the FPCB strip 3 connects to the flexible hollow tube 1 through means 4 and through mounting points in means 5, like nozzles, fittings, branch pipes, couplings, unions, ferrules, clutches, clamps. The means 4 can be connected directly to the FPCBS 3 or through connecting points 8 from prior art means.

The flexible hollow tube 1 being at internal air or gas pressure 2 protects the flexible FPCBS 3 also from long lasting chemical effects caused by water and other chemical elements in it. The said pressure 2 substantially reduces said permeation through the flexible hollow tube 1 materials and micro-cracks, and other possible breaches.

FIGS. 2A, 2B, 2C, 2D, 3A, 3D, 3C show that the connection of the electrical wires 10 to the FPCB strip are also protected by the flexible hollow tube 1 and air or gas pressure 2. The air or gas pressure 2 is created by source of the pressure 11 that connects to one of the ends of the flexible hollow tube 1. One of the possible connections can be viewed at FIG. 2A. Connection 7 is done by separating air pressure supply 11 and sealed outlet 9 for electrical wires 10. Electrical wires 10 are going to power supply defined as “P” and digital control/communicating devices defined as “C”. On the other side electrical wires 10 connected to the FPCBS 3 directly or through the connecting points 8 that also can be used for connection with means 4.

At FIG. 2B there is embodiment with the weight 12 that attached along the flexible hollow tube 1 by spinning around it. The embodiment is shown in a swimming pool basin 20. The weight 12 gives negative buoyancy for the flexible hollow tube 1 and keep it at the bottom. At FIG. 2B means 5 are using to block gas pressure dissipation and to connect connection 7. Preferably is to keep connection 7 out of the swimming pool water and somewhere near “P” and “C” sources. This can be easily done by elongating the flexible hollow tube 1. At FIG. 2B the shown angle of the flexible hollow tube 1 doesn't have any special effect on the embodiment. The said angel can be of any value allowable by the flexible hollow tube 1 mechanical properties.

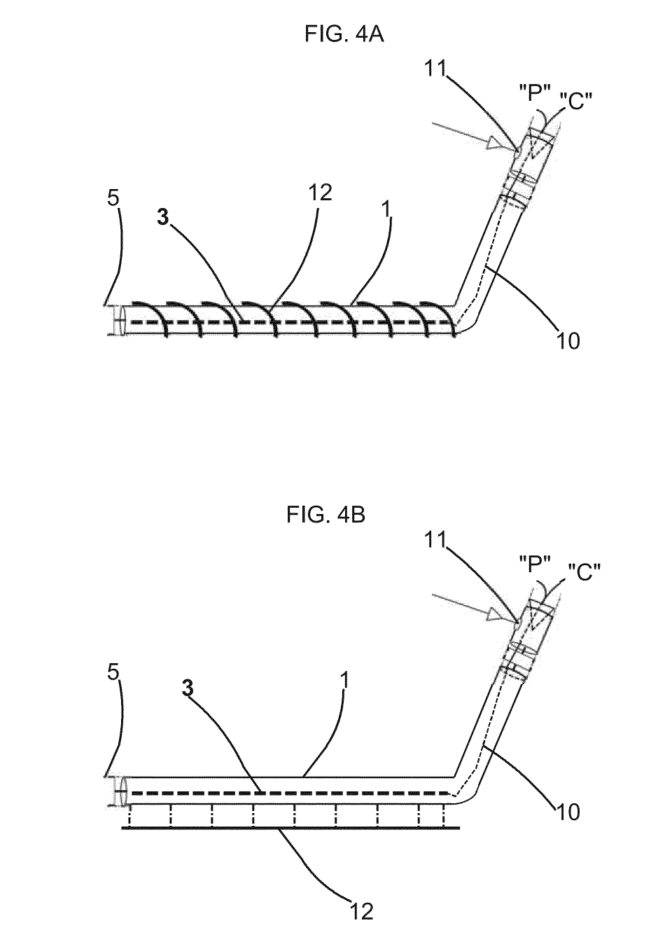

FIGS. 4A and 4B shows variations of weights 4 attachments to the flexible hollow tube 1. One is attached by spinning it around the flexible hollow tube. The other is linear attachment.

FIGS. 3A, 3B, and 3C show a sectional view of the embodiments.

1. A device to protect electrical circuits in a flexible printed circuit board strip from mechanical and long lasting chemical effects, comprising:
a. a flexible printed circuit board strip placed inside a flexible hollow tube,
b. said flexible hollow tube has dimensions allowing said flexible printed circuit board strip to turn around it longitudinal axis,
c. said flexible hollow tube has air or any other gas pressure inside it,
d. at least one end of said flexible hollow tube has means for connection of pressure source of air or other gas,
e. at least one end of said flexible hollow tube has means for sealed connection of electrical wires going from said flexible printed circuit board strip to power supply and or control device.

2. The flexible hollow tube of claim 1 withstands pressure from 1 bar and over.

3. The flexible hollow tube of claim 1 has length more than 3 meters.

4. The flexible hollow tube of claim 1 is made of reinforced or not reinforced polymer material.

5. The flexible hollow tube of claim 1 is of a round, or square, or rectangle, or pentagon, or hexagon, or heptagon, or octagon, or nonagon, or decagon cross-section shape.

6. The flexible hollow tube of claim 1 has inserted or incut means like nozzles, fittings, branch pipes, couplings, unions, ferrules, clutches, clamps, caps for purposes of connecting air pressure source, sealed connection of electrical wires, elongation of the flexible hollow tube, holding of air pressure, binding or bracing of flexible printed circuit board strip inside the flexible hollow tube, connecting of weights to hold or restrain the flexible hollow tube.

7. The flexible hollow tube of claim 1 has a weight or weights attached along the flexible hollow tube.

8. Said weights of claim 7 are attached by spinning around the flexible hollow tube.

9. The flexible printed circuit board strip of claim 1 is bind to said inserted or incut means of claim 6 through springs or elastic materials for purposes of compensating differences in the elasticity of the flexible printing circuit board strip and the flexible hollow tube, and restricts the flexible printing circuit board strip to twist along longitudinal axis.
